(19) United States
(12) Patent Application Publication
(10) Pub. No.: US 2017/0069823 A1
(43) Pub. Date: Mar. 9, 2017

(54) NONLINEAR VIBRATION ENERGY HARVESTING SYSTEM

(71) Applicant: Michael Karpelson, Newton, MA (US)

(72) Inventor: Michael Karpelson, Newton, MA (US)

(21) Appl. No.: 15/199,986

(22) Filed: Jul. 1, 2016

Related U.S. Application Data
(60) Provisional application No. 62/187,255, filed on Jul. 1, 2015.

(51) Int. Cl. H01L 41/113; H02K 1/27; H02K 3/04; H02N 2/18; H02K 35/02

(52) U.S. Cl. CPC H01L 41/1136; H02N 2/186; H02K 35/02; H02K 3/04; H02K 1/27

(57) ABSTRACT

A system for harvesting energy from mechanical motion and/or vibrations is disclosed. The system incorporates a nonlinear double pendulum mechanism. The nonlinear mechanism can be mounted on a frame that is fixed to a moving or vibrating object. A transducer can be coupled to the frame and/or the nonlinear mechanism in order to convert the relative motion of the frame and the nonlinear mechanism into electrical energy or stored mechanical energy. The recovered energy can be used to provide primary or supplementary power to certain electronic and mechanical devices.

### CROSS REFERENCE TO RELATED APPLICATIONS

This application claims the benefit under 35 U.S.C. §119(e) of U.S. Provisional Application No. 62/187,255 filed Jul. 1, 2015, the content of which is incorporated herein by reference in its entirety.

### FIELD OF THE INVENTION

The present invention concerns a nonlinear vibration energy harvesting system based on a double pendulum mechanism.

### BACKGROUND

The harvesting of energy from mechanical vibrations or other motion offers a promising method to provide power to certain types of electronic devices (e.g. remote sensors) or to extend the operating time of battery-powered electronic devices (e.g. wearable electronics). Most vibration energy harvesters are termed “inertial harvesters” because they draw power from the relative motion of a proof mass and a fixed frame from which the mass is suspended.

Inertial harvesters may furthermore be resonant or non-resonant. Resonant harvesters are highly efficient at extracting energy from a single vibration frequency, but their performance decreases significantly at other frequencies. Many operating scenarios for inertial energy harvesters, especially those involving human motion, exhibit a wide range of vibration frequencies. Consequently, there has been significant interest in non-resonant inertial harvesters with a broadband frequency response. Such devices typically rely on nonlinear mechanisms to suspend the proof mass from the fixed frame, such as bistable mechanisms (e.g. U.S. Pat. No. 8,174,167).

Linear energy harvesting devices based on a single pendulum are used extensively in automatic and quartz wristwatch movements; in the former, the motion of the pendulum stemming from the motion of the wearer's arm is used to store energy in the mainspring of the watch, while in the latter, the motion of the pendulum is coupled to a miniature electrical generator. Wristwatch energy harvesters need only provide enough energy to power the movement of the watch, which requires much less power than most sensor nodes or wearable devices (e.g. fitness trackers, smart watches, etc.).

Despite significant advances in broadband vibration energy harvesting, a system that a) generates power from human motion alone, b) generates enough power to have a significant effect on the operating time of current-generation wearable devices or implantable medical devices, and c) is sufficiently compact to be integrated into current-generation wearable devices or implantable medical devices, remains elusive.

### SUMMARY

A nonlinear vibration energy harvesting system is described herein, where various embodiments of the apparatus may include some or all of the elements and features described below.

The nonlinear vibration energy harvesting system comprises a double pendulum mechanism mounted on a frame that is fixed to a moving or vibrating object, and a means of converting the relative motion of the double pendulum mechanism and the frame to electrical or stored mechanical energy.

### BRIEF DESCRIPTION OF THE DRAWINGS

FIG. 1 shows, in schematic top view, the basic structure of the double pendulum mechanism and frame.

FIG. 2 shows, in schematic top view, two possible implementations of the rotary joints of the double pendulum mechanism: rotational bearings and elastic flexures.

FIG. 3 shows, in schematic top view, the integration of elastic mechanical end stops into the double pendulum mechanism.

FIG. 4 shows, in schematic top and side views, a means of converting the motion of the double pendulum to electrical energy by means of permanent magnets, magnetic core, and windings oriented at an angle with respect to one another.

FIG. 5 shows, in schematic top and side views, a means of converting the motion of the double pendulum to electrical or stored mechanical energy by means of transmitting the motion of the rotary joints to an electrical generator or mechanical energy storage device.

FIG. 6 shows, in schematic top and side views, a means of converting the motion of the double pendulum to electrical energy by means of an axial flux permanent magnet generator with multiple windings.

### DETAILED DESCRIPTION

The foregoing and other features and advantages of various aspects of the invention(s) will be apparent from the following, more-particular description of various concepts and specific embodiments within the broader bounds of the invention(s). Various aspects of the subject matter introduced above and discussed in greater detail below may be implemented in any of numerous ways, as the subject matter is not limited to any particular manner of implementation. Examples of specific implementations and applications are provided primarily for illustrative purposes.

Unless otherwise defined, used or characterized herein, terms that are used herein (including technical and scientific terms) are to be interpreted as having a meaning that is consistent with their accepted meaning in the context of the relevant art and are not to be interpreted in an idealized or overly formal sense unless expressly so defined herein. For example, if a particular composition is referenced, the composition may be substantially (though not perfectly) pure, as practical and imperfect realities may apply; e.g., the potential presence of at least trace impurities (e.g., at less than 1 or 2%) can be understood as being within the scope of the description; likewise, if a particular shape is referenced, the shape is intended to include imperfect variations from ideal shapes, e.g., due to manufacturing tolerances.

Although the terms, first, second, third, etc., may be used herein to describe various elements, these elements are not to be limited by these terms. These terms are simply used to distinguish one element from another. Thus, a first element, discussed below, could be termed a second element without departing from the teachings of the exemplary embodiments.

Spatially relative terms, such as “above,” “below,” “left,” “right,” “in front,” “behind,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

Further still, in this disclosure, when an element is referred to as being “on,” “connected to,” “coupled to,” “in contact with,” etc., another element, it may be directly on, connected to, coupled to, or in contact with the other element or intervening elements may be present unless otherwise specified.

The terminology used herein is for the purpose of describing particular embodiments and is not intended to be limiting of exemplary embodiments. As used herein, singular forms, such as “a” and “an,” are intended to include the plural forms as well, unless the context indicates otherwise. Additionally, the terms, “includes,” “including,” “comprises” and “comprising,” specify the presence of the stated elements or steps but do not preclude the presence or addition of one or more other elements or steps.

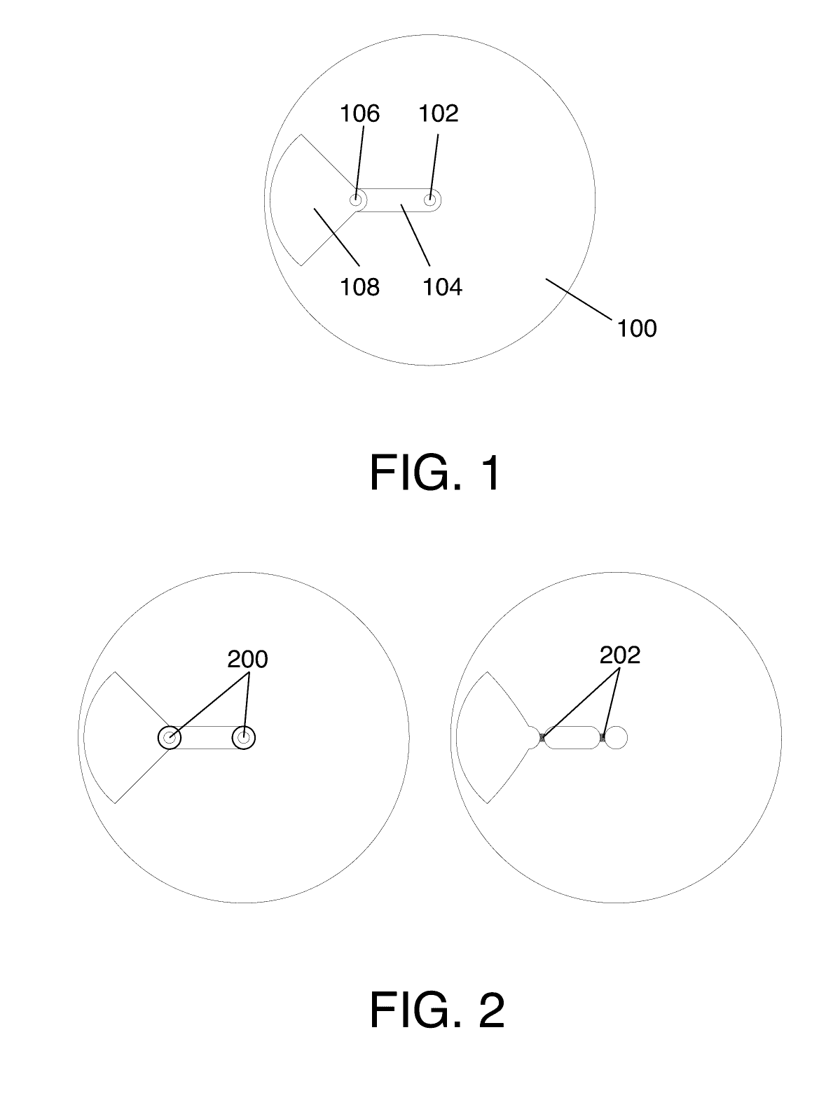

The double pendulum is a well-known mechanical system consisting of a first pendulum with a second pendulum mounted on the moving part of the first pendulum. The double pendulum exhibits rich, nonlinear dynamic behavior that is highly sensitive to initial conditions and excitation frequencies. FIG. 1 shows, in schematic top view, the basic structure of a double pendulum inertial mechanism comprising fixed frame 100, rotary joint 102 connecting the fixed frame 100 to the first link 104, and rotary joint 106 connecting first link 104 to proof mass link 108. In a typical embodiment, fixed frame 100 is rigidly coupled to a source of vibration or mechanical excitation. During the operation of the device, this vibration or mechanical excitation may, at various times, cause link 104 to rotate about the axis defined by rotary joint 102, and/or proof mass link 108 to rotate about the axis defined by rotary joint 106. It will be apparent to one skilled in the art that altering the lengths, masses, and inertias of link 104 and proof mass link 108 will alter the dynamic behavior of the double pendulum, allowing the system to be customized to respond optimally to various applications with diverse mechanical excitation profiles.

One skilled in the art will appreciate that the rotary joints 102 and 106 in FIG. 1 may be implemented in a number of ways. FIG. 2 shows, in schematic top view, a possible embodiment using rotational bearings 200, as well as a possible embodiment using elastic flexures 202. Possible physical instantiations of rotational bearings 200 include but are not limited to low-friction sleeve bearings, ball bearings, and jewel bearings. Possible physical instantiations of elastic flexures 202 include but are not limited to rubbers, flexible polymers, and metals in flat spring, torsion spring, or other spring configurations.

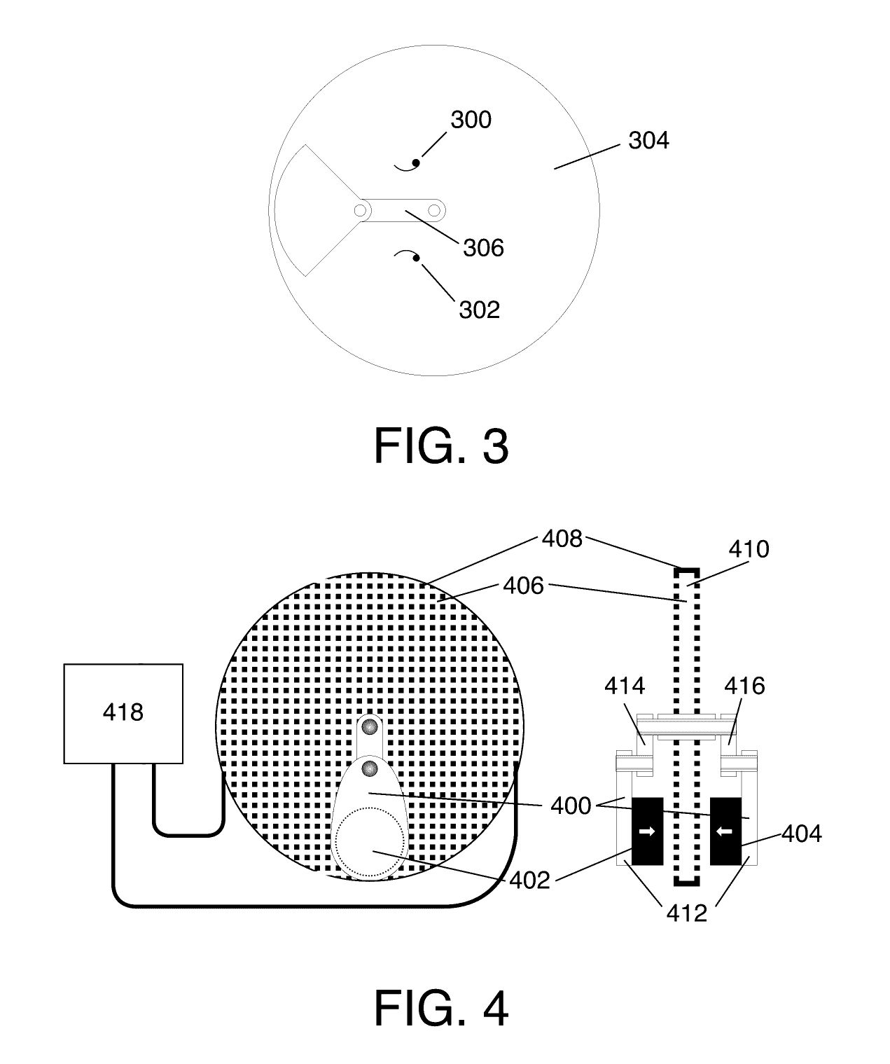

FIG. 3 shows, in schematic top view, an alternate embodiment that incorporates elastic mechanical end stops 300 and 302, rigidly coupled to fixed frame 304, that arrest the motion of first link 306 at predetermined points. End stops 300 and 302 may be used in applications with certain mechanical excitation profiles to increase the amount of mechanical energy coupled from the external mechanical excitation source into the double pendulum mechanism. Possible physical instantiations of elastic end stops 300 and 302 include but are not limited to springs, elastic bumpers, and other compressible elements. It will be apparent to one skilled in the art that the position and maximum deflection of end stops 300 and 302 will further affect the dynamic behavior of the system, allowing the system to be tuned for diverse operating conditions.

One of the primary design challenges in a double pendulum energy harvester is the energy transduction mechanism, which is complicated by the presence of two rotary joints. FIG. 4 shows, in schematic top and side views, one embodiment of an energy transduction mechanism where the proof mass 400 of the double pendulum incorporates permanent magnets 402 and 404. The motion of the double pendulum causes magnets 402 and 404 (arrows denote polarization direction) to move over perpendicular electrical windings 406 and 408, which are wound around magnetic core portion 410 (hereafter termed the “winding core”). Winding core 410, along with magnetic core portions 412 (hereafter termed the “backplates”), and the pendulum links 414 and 416 are manufactured from magnetic material with a high permeability. This arrangement confines and guides the magnetic field from permanent magnets 402 and 404. The motion of magnets 402 and 404 relative to windings 406 and 408 induces an electrical current in one or both windings, depending on the specific motion of the proof mass link. It will be apparent to one skilled in the art that these currents may be conditioned by an appropriate power electronic circuit 418 to directly power an electronic device or store energy in an electrical storage device. This configuration is functionally equivalent to a voice coil actuator/generator, and may be implemented with magnets (402 AND 404) on both sides of the windings, or only one magnet (402 OR 404) on one side of the windings.

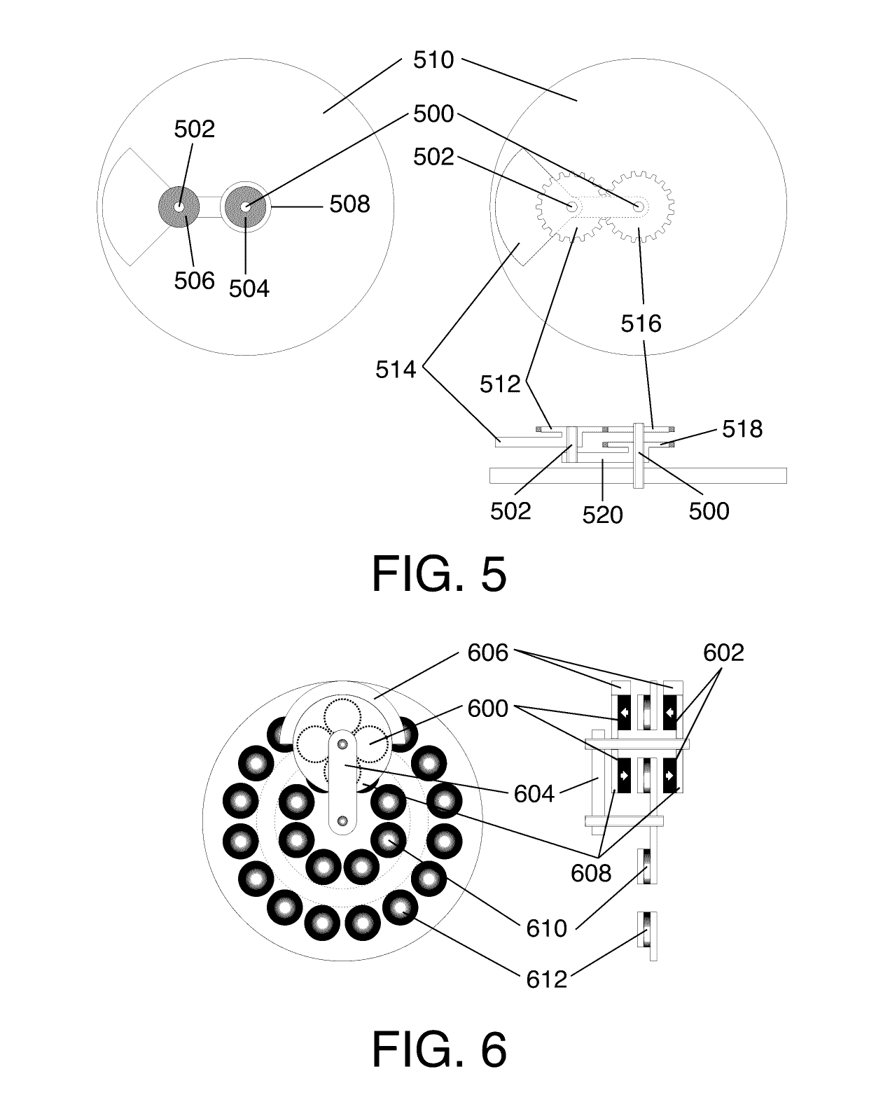

FIG. 5 shows, in schematic top and side views, two additional embodiments of the energy transduction mechanism. Here, rotary joints 500 and 502 are coupled directly to rotational electric generators 504 and 506, which may be electromagnetic or piezoelectric (e.g. the action of the generator may repeatedly pluck a piezoelectric cantilever). In the event that the rotation of joint 500 may be continuous (i.e. not limited by mechanical end stops or maximum flexure rotation), electrical wiring from generators 504 and 506 may require an optional slip ring connector 508. Alternatively, the rotation of joints 500 and 502 may be transmitted to the fixed frame 510 via gear 512, connected to proof mass link 514, and idler gear 516, which is coaxial with rotary joint 500, and gear 518, connected to first pendulum link 520. Gears 516 and 518 may then interface with any rotational generator or a mechanical energy storage system (e.g. mainspring).

FIG. 6 shows, in schematic top and side views, an additional embodiment of the energy transduction mechanism. Here, magnet assemblies 600 and 602 (arrows denote polarization direction) form part of the proof mass link 606. The magnetic field of the magnets is further enhanced and confined by backplates 608, manufactured from magnetic material with a high permeability. The rotation of first pendulum link 604 and the proof mass link 606 causes the magnets with alternating polarization directions to pass over independently wired coil arrays 610 and 612, inducing electrical currents in one or both coil assemblies. It will be apparent to one skilled in the art that these currents may be conditioned by an appropriate power electronic circuit to directly power an electronic device or store energy in an electrical storage device. This embodiment bears similarities to an axial flux electric generator.

What is claimed is:

1. A nonlinear vibration energy harvesting system, comprising:
a. a rigid fixed frame;
b. a first pendulum link coupled to the fixed frame via a rotary joint;
c. a second proof mass link coupled to the first link via a rotary joint;
d. an energy transduction mechanism used to convert the motion of the first and second links relative to the fixed frame to electrical energy, or a mechanical energy storage mechanism to directly collect and store the energy of this motion.

2. The nonlinear vibration energy harvesting system of claim 1, where the rotary joints may be implemented using rotational bearings or elastic flexures.

3. The nonlinear vibration energy harvesting system of claim 1, where additional elastic mechanical end stops are incorporated into the system to restrict the motion of the first pendulum link.

4. The nonlinear vibration energy harvesting system of claim 1, where the energy transduction mechanism comprises:
a. one or more permanent magnets rigidly coupled to the proof mass link;
b. two or more conductive windings arranged at an angle between 0 and 90 degrees with respect to one another, rigidly coupled to the fixed frame;
c. a magnetic core arrangement configured to guide the magnetic field of the permanent magnets over the windings.

5. The nonlinear vibration energy harvesting system of claim 1, where the energy transduction mechanism comprises two rotational electromagnetic generators coupled to the two rotary joints.

6. The nonlinear vibration energy harvesting system of claim 1, where the energy transduction mechanism comprises two piezoelectric cantilevers plucked, either by direct physical contact or by a non-contact method, by structures coupled to the two rotary joints.

7. The nonlinear vibration energy harvesting system of claim 1, where the motion of the two rotary joints is transmitted via gears to the fixed frame of the system, and where said gears are coupled to one or more electrical generators.

8. The nonlinear vibration energy harvesting system of claim 1, where the energy transduction mechanism comprises:
a. one or more permanent magnet assemblies with alternating polarization directions rigidly coupled to the proof mass link;
b. one or more independently wired coil assemblies rigidly coupled to the fixed frame;
c. magnetic backplate arrangements configured to guide the magnetic field of the permanent magnets over the coils during the motion of the pendulum links.
